(19) United States
(12) Patent Application Publication
(10) Pub. No.: US 2025/0101851 A1
(43) Pub. Date: Mar. 27, 2025

(54) OPTIMIZING TUBULAR STRING WRAPS

(71) Applicant: Nabors Drilling Technologies USA, Inc., Houston, TX (US)

(72) Inventors: Varadaraju GANDIKOTA, Cypress, TX (US); Brandon ROSLER, Conroe, TX (US); Tino HADAD, Spring, TX (US); Robert Bryan HELLER, SR., Gilmer, TX (US)

(21) Appl. No.: 18/893,031

(22) Filed: Sep. 23, 2024

Related U.S. Application Data
(60) Provisional application No. 63/585,042, filed on Sep. 25, 2023.

(51) Int. Cl. E21B 44/00; E21B 47/00; E21B 49/00; G06F 30/28

(52) U.S. Cl. CPC E21B 44/00; E21B 47/00; E21B 49/00; G06F 30/28; E21B 2200/20

(57) ABSTRACT

A method of optimizing a wraps in real-time in a subterranean operation, that can include determining, via a statistical model, an equivalent confined compressive rock strength (ECCRS) profile along a future wellbore, receiving the ECCRS profile at an wrap optimizer; receiving physical parameters of a tubular string at the wrap optimizer, and simulating in real-time, via the wrap optimizer, a simulated wrap of the tubular string through a portion of a subterranean formation based on the ECCRS profile, the physical parameters of the tubular string, a friction profile of the future wellbore, and drilling parameters of a rig.

### CROSS-REFERENCE TO RELATED APPLICATION(S)

This application claims priority under 35 U.S.C. § 119 (c) to U.S. Provisional Application No. 63/585,042, entitled “OPTIMIZING TUBULAR STRING WRAPS,” by Varadaraju GANDIKOTA et al., filed Sep. 25, 2023, which is assigned to the current assignee hereof and incorporated herein by reference in its entirety.

### FIELD OF THE DISCLOSURE

The present invention relates, in general, to the field of drilling and processing of wells. More particularly, present embodiments relate to a system and method for optimizing wraps (or oscillations) of a drill string during slide drilling of subterranean operations.

### BACKGROUND

Optimum wraps (or oscillations) are commonly predicted based on wraps performed in previously drilled wellbores. This method does not appear to provide clear insight into the drilling behavior of the current wellbore and does not appear to provide for updates based on the current drilling behavior. Therefore, improvements in methods and systems for determining optimum wraps are continually needed.

### SUMMARY

This summary is provided to introduce a selection of concepts that are further described below in the detailed description. This summary is not intended to identify indispensable features of the claimed subject matter, nor is it intended for use as an aid in limiting the scope of the claimed subject matter.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

One general aspect includes a method of optimizing tubular string wraps in real-time during a subterranean operation. The method can include determining, via a rig controller, a friction model of a wellbore as a function of depth; simulating, via a physics-based model, a digital twin, where the digital twin simulates interactions between a tubular string and the wellbore based on the friction model; adjusting, via the physics-based model, parameters of estimated wraps for oscillating the tubular string in the wellbore in the digital twin simulation; identifying, via the digital twin, optimum parameters for simulated wraps; communicating, via the physics-based model, the optimum parameters to the rig controller; and producing, via the rig controller, actual wraps of the tubular string in the wellbore based on the optimum parameters.

Other embodiments of this aspect include corresponding computer systems, apparatus, and computer programs recorded on one or more computer storage devices, each configured to perform the actions of the methods.

### BRIEF DESCRIPTION OF THE DRAWINGS

These and other features, aspects, and advantages of present embodiments will become better understood when the following detailed description is read with reference to the accompanying drawings in which like characters represent like parts throughout the drawings, wherein:

FIG. 1 is a representative view of a rig used to perform subterranean operations, in accordance with certain embodiments;

FIG. 2 is a representative partial cross-section view of a rig used to perform subterranean operations, in accordance with certain embodiments;

FIG. 3 is a representative partial cross-section view of wellbore being drilled using a bottom hole assembly (BHA), in accordance with certain embodiments;

FIG. 4 is a representative plot of proposed and actual paths of the wellbore of FIG. 2 being drilled (or previously drilled) that illustrate deviations from a desired path defined in a well plan, in accordance with certain embodiments;

FIG. 5 is a representative functional block diagram of a rig controller that can control rig equipment of the rig 10 and perform methods of the current disclosure (e.g., wrap optimization), in accordance with certain embodiments;

FIG. 6 is a representative flow diagram of a method for determining an equivalent confined compressive rock strength (ECCRS) profile of a future wellbore, in accordance with certain embodiments; and

FIG. 7 is a representative functional block diagram of a wrap optimizer for real-time control of wraps of a tubular string during slide drilling operations of a future wellbore, in accordance with certain embodiments.

FIG. 8 is a representative flow diagram of a method 300 for real-time control of wraps of a tubular string during slide drilling operations of a wellbore, in accordance with certain embodiments.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

As used herein, the terms “comprises,” “comprising,” “includes,” “including,” “has,” “having,” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

The use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise.

The use of the word “about”, “approximately”, “generally”, or “substantially” is intended to mean that a value of a parameter is close to a stated value or position. However, minor differences may prevent the values or positions from being exactly as stated. Thus, differences of up to ten percent (10%) for the value are reasonable differences from the ideal goal of exactly as described. A significant difference can be when the difference is greater than ten percent (10%).

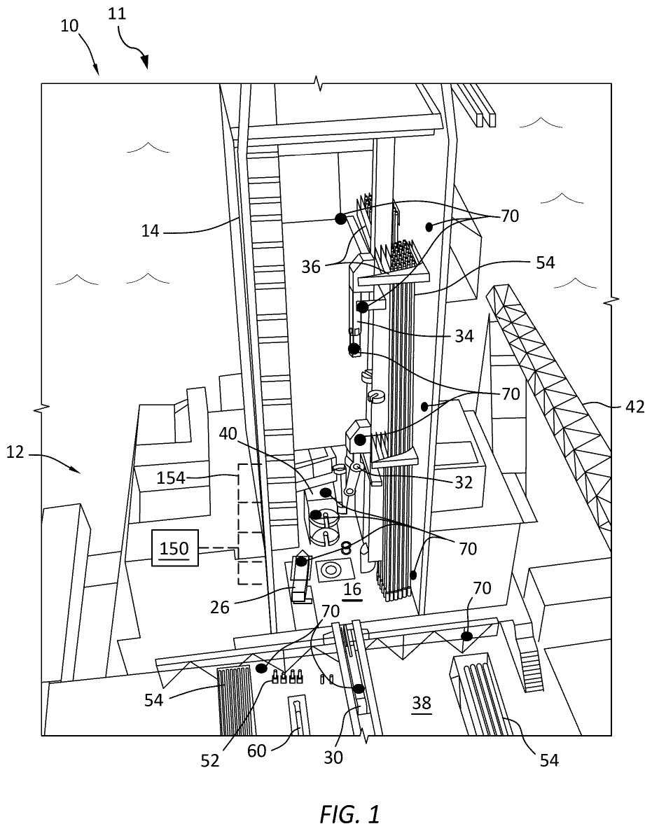

As used herein, “tubular” refers to an elongated cylindrical tube and can include any of the tubulars manipulated around a rig, such as tubular segments, tubular stands, tubulars, and tubular string, but not limited to the tubulars shown in FIG. 1. Therefore, in this disclosure, “tubular” is synonymous with “tubular segment,” “tubular stand,” and “tubular string,” as well as “pipe,” “pipe segment,” “pipe stand,” “pipe string,” “casing,” “casing segment,” or “casing string.”

FIG. 1 is a representative view of a rig 10 at a rig site 11 that can be used to perform subterranean operations, in accordance with certain embodiments. The rig 10 is shown as an offshore rig, but it should be understood that the principles of this disclosure are equally applicable to onshore rigs as well. The example rig 10 can include a platform 12 with a derrick 14 extending above the platform 12 from the rig floor 16. The platform 12 and derrick 14 provide the general super structure of the rig 10 from which the rig equipment is supported. The rig 10 can include a horizontal storage area 38, pipe handlers 30, 32, 34, a drill floor robot 26, an iron roughneck 40, a crane 42, fingerboard storage 36, and a plurality of sensors 70 distributed at various locations on the rig 10. The sensors 70 can be any type of sensors that can detect various characteristics of the subterranean operation being performed by the rig 10.

The sensors 70 can be two dimensional (2D) cameras, three dimensional (3D) cameras, infrared cameras, closed circuit television (CCTV) cameras, X-ray sensors, light detection and ranging (LiDAR) sensors, proximity sensors, strain gauges, torque sensors, accelerometers, optical sensors, laser sensors, physical contact sensors, contact sensors with encoders, audio sensors, pressure sensors, temperature sensors, environmental sensors, gas sensors, liquid sensors, or other suitable sensors for detecting characteristics of the rig environment or rig operations. The sensors 70, as well as other rig environment on the rig 10, can be communicatively coupled to a rig controller 150 via a network 154, with the network 154 being wired or wirelessly connected to the sensors 70 or rig environment.

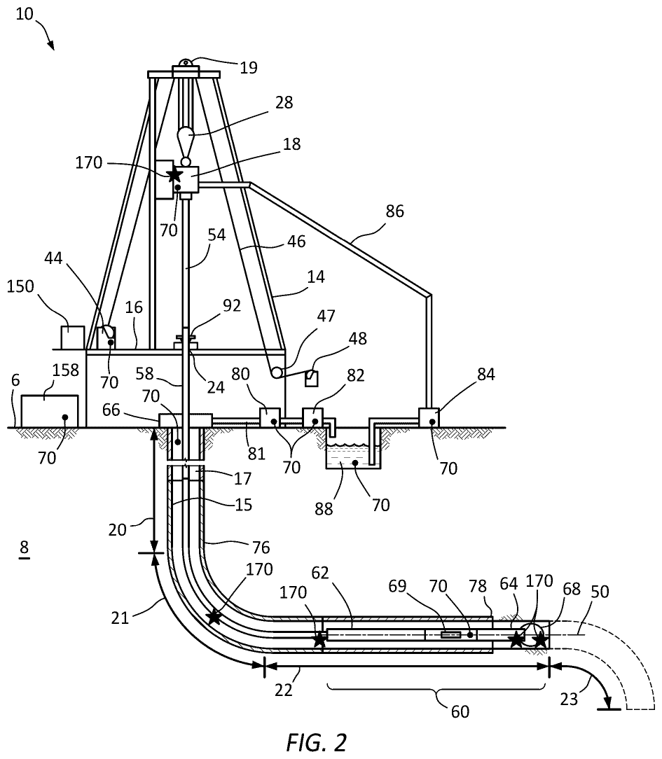

The sensors 70 can be disposed on stationary locations (such as on or above the horizontal storage area 38, at various points along the fingerboard storage 36, on the derrick 14, on the platform 12, etc.). The sensors 70 can also be disposed on robotic equipment, such as the drill floor robot 26, the iron roughneck 40, the pipe handlers 30, 32, 34, a top drive 18 (see FIG. 2), and the crane 42. Some of the tubulars that can be used during subterranean operations is shown in the horizontal storage area 38 and the fingerboard storage 36, such as the tubulars 54, the tools 52, the bottom hole assembly (BHA) 60, and tubulars 54. The tools 52 can include centralizers, subs, slips, subs with sensors, adapters, etc. The BHA 60 can include drill collars, instrumentation, and a drill bit 68 (see FIG. 2).

A digital twin simulation can be used in drilling operations to create a virtual model of the wellbore 15 and operations of the rig and rig equipment. The virtual digital twin can simulate the drilling process and optimize drilling parameters in real-time especially when it can operate at the edge on a rig 10. As described herein, a physics-based model (e.g., a fast-running time domain model based on mixed multi-body mechanics and flexible body methods) can form the basis of the digital twin simulation. The workflow can automatically recognize drilling rig states (rotary or slide drilling) based on the current well plan and sensors 70, and connection makeup to start and stop the predictive model. The current wrap optimizer 100 can be used to optimize the wraps (or oscillations) of the tubular string 58 during slide drilling operations. The rig controller 150 can initiate the digital twin simulation as needed to predict or track performance of the wraps.

Another benefit of digital twin simulation is that virtual sensors 170 can be placed in the simulation to report on whatever drilling parameter is of interest to the operators or the rig controller 150. As shown, these virtual sensors 170 can be virtually placed at any location of the drilling operation in the simulation unlike physical sensors 70 which are restricted, due to physical factors, from being placed anywhere (e.g., ahead of the bit 68). These virtual sensors 170 can be used to detect rotation of the tubular string 58 at any location along the tubular string 58 as well as in the BHA 60. This digital twin allows for visibility into the progression of the wraps along the tubular string 58 to evaluate performance of particular wrap parameters. Therefore, with this performance feedback, the wrap parameters can be optimized.

FIG. 2 is a representative partial cross-sectional front view of a rig 10 at a rig site 11 being used to drill a wellbore 15 in a subterranean formation 8, in accordance with certain embodiments. FIG. 1 shows a land-based rig 10 located on a surface 6, but the principles of this disclosure can equally apply to off-shore rigs, as well, where “off-shore” refers to a rig with water between the rig floor and the earth surface 6. Rig 10 can include a top drive 18 with a drawworks 44, sheaves 19, traveling block 28, anchor 47, and reel 48 used to raise or lower the top drive 18 via cable 46. A derrick 14 extending from the rig floor 16, can provide the structural support of the rig equipment for performing subterranean operations (e.g., drilling, treating, completing, producing, testing, etc.).

The rig can be used to extend a wellbore 15 through the subterranean formation 8 by using a tubular string 58 having a bottom hole assembly (BHA) 60 at its lower end. The BHA 60 can include a drill bit 68 and multiple drill collars 62, with one or more of the drill collars including one or more sensors 70 or one or more tools 69 for Logging While Drilling (LWD) or Measuring While Drilling (MWD) operations. During drilling operations, drilling mud can be pumped from the surface 6 into the tubular string 58 (e.g., via pumps 84 supplying mud to the top drive 18 via the standpipe 86) to cool and lubricate the drill bit 68 and to transport cuttings to the surface via an annulus 17 between the tubular string 58 and the wellbore 15.

The returned mud can be directed to the mud pit 88 from a rotating control device 66, through the flow line 81, to the shaker 80. A fluid treatment 82 can inject additives as desired to the mud to condition the mud appropriately for the current well activities and possibly future well activities as the mud is being pumped to the mud pit 88. Pump 84 can pull mud from the mud pit 88 and drive it to the top drive 18, via standpipe 86, to continue circulation of the mud through the tubular string 58.

The tubular string 58 can extend into the wellbore 15, with the wellbore 15 extending through the surface 6 into the subterranean formation 8. With a segmented tubular string 58, when tripping the tubular string 58 into the wellbore 15, tubulars 54 are sequentially added to the tubular string 58, e.g., via a top drive 18 and slips 92 (at well center 24) that cooperate together to extend the length of the tubular string 58 into the subterranean formation 8. When the tubular string 58 is a wireline or coiled tubing, the tubular string 58 can be uncoiled from a spool and extended into the wellbore 15. With a segmented tubular string 58, when tripping the tubular string 58 out of the wellbore 15, tubulars 54 are sequentially removed from the tubular string 58 to reduce the length of the tubular string 58 extending into the subterranean formation 8. With a wireline or coiled tubing, the tubular string 58 can be coiled onto a spool when being pulled out of the wellbore 15.

The wellbore 15 can have a casing string 76 installed in the wellbore 15 and extending down to a casing shoe 78. The portion of the wellbore 15 with the casing string 76 installed, can be referred to as a cased wellbore. The portion of the wellbore 15 below the shoe 78, without casing, can be referred to as an “uncased” or “open hole” wellbore. The wellbore 15 can be extended by rotating the drill bit 68 and cutting into the earthen formation 8. A proposed path for a wellbore 15 (e.g., a roadmap defined by a well plan 163) can include one or more vertical or deviated portions 20, 21, 22, 23. A vertical portion 20 can be the first portion of the wellbore 15 extending into the earthen formation from the surface. Deviated portions (e.g., portions 21, 22, 23) can be portions of the wellbore 15 that deviate from the vertical portion 20, such as when the bit 68 is steered in a non-vertical direction from the vertical portion 20.

The vertical and deviated portions 20, 21, 22, 23 can be drilled by rotary drilling or slide drilling. Rotary drilling generally refers to when the drill bit 68 is rotated by rotating the whole tubular string 58 including the BHA 60. Slide drilling generally refers to when the drill bit 68 is rotated by a downhole motor 64 (e.g., a mud motor) in the BHA 60 and the tubular string 58 is not used to rotate the drill bit 68. Slide drilling is generally used to steer the drill bit 68 in a deviated direction from straight ahead.

To begin slide drilling, the drill string 58 can be rotated until the toolface of the BHA 60 is at the desired azimuthal position downhole to steer the drill bit 68 in the desired direction. The downhole motor 64 can then begin rotating the drill bit 68, which will bore into the formation at the desired direction. To change the direction, the toolface can be rotated to a new desired azimuthal orientation and the downhole motor 64 can continue rotating the drill bit 68 to proceed in the new desired direction. Therefore, the orientation of the toolface generally determines the direction the tubular string 58 progresses in the formation 8.

Wells with complex structures such as horizontal wells or extended reach wells have become more widely used to reach production zones that are further and further below the surface 6. In these complex structure wells, large friction forces between tubular string 58 and the wellbore 15 can occur. To effectively reduce the friction, wrapping (or oscillating) the tubular string 58 back and forth without substantially changing the tool face angle helps reduce wellbore friction and can increase the weight that the tubular string 58 can provide to the drill bit 68. This can improve the rate of penetration (ROP) as opposed to not wrapping the tubular string 58 during slide drilling operations.

The current disclosure provides systems and methods for estimating the wraps, performing the estimated wraps, simulating the wraps, comparing simulated wraps with actual wraps, and automatically adjusting the wraps during slide drilling operations. By simulating the wraps and automatically adjusting them in near real-time, the system can maintain optimal wraps of the tubular string 58 thereby maximizing drilling efficiency for slide drilling operations.

A rig controller 150 can be used to control rig operations including controlling various rig equipment, such as a pipe handler, the top drive 18, drawworks 44, an iron roughneck, fingerboard equipment, imaging systems, various other robots on the rig 10 (e.g., a drill floor robot), rig power systems 158, mud pumps 84, shaker 80, a fluid treatment 82, other equipment for rig operations. The rig controller 150 can control the rig equipment autonomously (e.g., without periodic operator interaction,), semi-autonomously (e.g., with limited operator interaction such as initiating a subterranean operation, adjusting parameters during the operation, etc.), or manually (e.g., with the operator interactively controlling the rig equipment via remote control interfaces to perform the subterranean operation).

The rig controller 150 can include one or more processors with one or more of the processors distributed about the rig 10, such as in an operator's control hut, in a pipe handler, in an iron roughneck, in a vertical storage area, in the imaging systems, in various other robots, in the top drive 18, at various locations on the rig floor 16 or the derrick 14 or the platform 12, at a remote location off of the rig 10, at downhole locations, etc. It should be understood that any of these processors can perform control or calculations locally or can communicate to a remotely located processor for performing the control or calculations. Each of the processors can be communicatively coupled to a non-transitory memory, which can include instructions for the respective processor to read and execute to implement the desired control functions or other methods described in this disclosure. These processors can be coupled via a wired or wireless network.

The rig controller 150 can collect data from various data sources around the rig (e.g., data from sensors 70) and downhole (e.g., sensor data via mud pulse telemetry, EM telemetry, etc.) and from remote data sources (e.g., suppliers, manufacturers, transporters, company men, remote rig reports, etc.) to monitor and facilitate the execution of the subterranean operation and to control wraps of the tubular string 58 during slide drilling operations.

During subterranean operations, such as drilling, various logging operations are generally performed to collect and store sensor data for later processing to provide visualization of parameters and characteristics of the wellbore and its surroundings. The processing can be performed by the rig controller 150 during the subterranean operation or after the subterranean operation is complete. A tool 69 can be included in the BHA 60 (or otherwise included in the tubular string 58) for performing logging or measuring operations at various times (or continuous) during the operation. Tool 69 can have a longitudinal center axis, which can correspond to the longitudinal center axis 50 of an internal bore of the BHA 60 (or tubular 54). Some of the logging/measuring operations can be to collect downhole sensor data of the wellbore 15 while the tubular string 58 is being rotated (such as for drilling, reaming, etc.). The data from downhole sensors 70 can be communicated to the surface via various telemetry methods for detection at the surface and decoded to retrieve the sensor data.

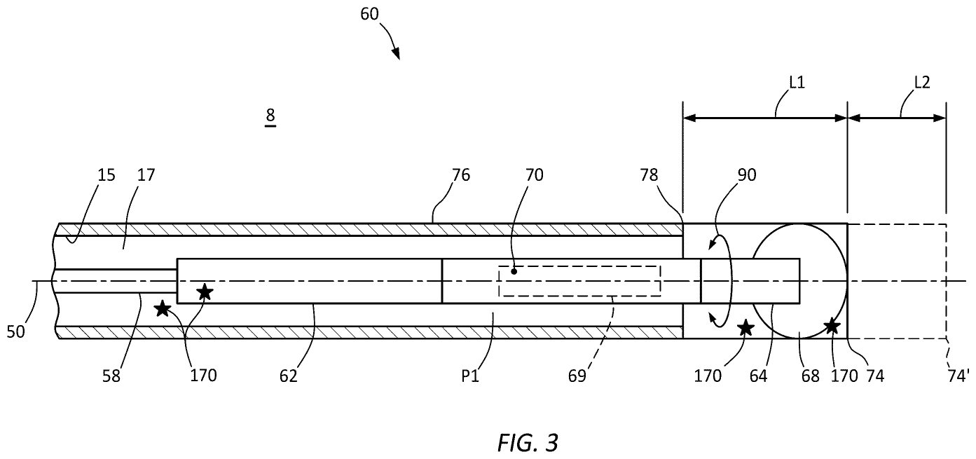

FIG. 3 is a representative partial cross-section view of a wellbore 15 being drilled using a bottom hole assembly (BHA) 60, in accordance with certain embodiments. A tubular string 58 can be used to further extend the wellbore 15 by rotating the drill bit 68, which can be done by cither driving the mud motor 64 without rotating the tubular string 58, rotating the tubular string 58 without driving the mud motor 64, or rotating both the mud motor 64 and the tubular string 58. When rotating the drill bit 68 (arrows 90), the tubular string 58 can be lowered to engage the drill bit 68 with the bottom 74 of the wellbore 15 and to increase weight on bit (WOB).

Drilling fluid can flow down through the tubular string 58 to exit the drill bit 68 and travel back to the surface via the annulus 17. As a desired WOB is applied to the drill bit 68 and the drill bit 68 is rotated, the drill bit 68 can progress along a path at a rate (e.g., distance/time).

The rate that the drill bit progresses along the path can be referred to as a rate of penetration (ROP) of the drill bit 68. The ROP represents the rate of progression of the drill bit 68 along the path that extends the wellbore 15 further into the subterranean formation 8. ROP during slide drilling operations can be greatly affected by the friction acting on the tubular string 58 while applying WOB. As stated above, wraps of the tubular string 58 can be used to reduce the friction acting on the tubular string 58 by changing static friction to dynamic friction.

For example, with a desired WOB, a desired RPM of the drill bit 68, and a desired flow rate of the drilling fluid, the drill bit 68 can advance from a bottom 74 of the wellbore 15 to a new bottom 74′ of the wellbore 15, where the drill bit 68 travels along a distance L2 in a time period T. Optimizing the wraps can facilitate applying the desired WOB during slide drilling operations. Calculating the actual wrap of the wellbore 15 can provide valuable feedback to well planning for future wellbores or the remainder of the current wellbore 15, especially regarding the actual wraps of the tubular string 58.

It may be desirable to predict future wraps of a tubular string 58 and optimize the wraps, for example, by maximizing wraps while maintaining a toolface position during slide drilling operations. Predicting future wraps of the tubular string 58 can be based on a friction profile of the wellbore 15 by depth and a physics-based model that simulates the tubular string 58 in the wellbore 15. The friction profile can be determined from the characteristics of the wellbore 15, characteristics of the tubular string 58, and a calculated Equivalent Confined Compressive Rock Strength (ECCRS) for uncased portions of the wellbore 15.

A physics-based model (e.g., an unsteady-state physics model or a fast running time domain analysis model), can predict wraps for the tubular string 58 in real time while simulating (e.g., digital twin) the interaction between the tubular string 58 and the wellbore 15 during slide drilling operations. The real time wrap predictions and associated parameters can be provided to an operator of the rig 10 or to the rig controller 150 for control of the rig 10 (e.g., automated control, semi-automated control, or manual control of the rig 10).

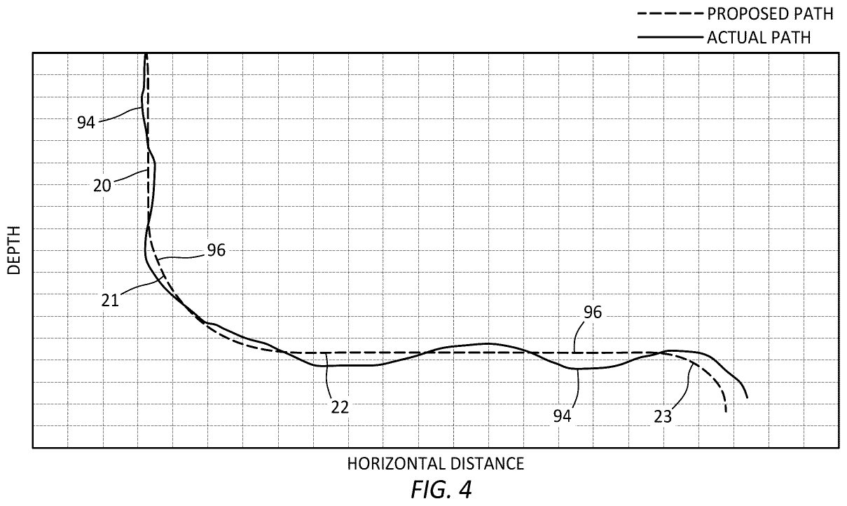

FIG. 4 is a representative plot of a proposed path 96 and an actual path 94 of the wellbore of FIG. 2 being drilled (or previously drilled) that illustrate deviations from the proposed path 96 defined in a well plan 163, in accordance with certain embodiments. The actual path 94 can be developed based on sensor data from the sensors 70 positioned about the rig equipment (including downhole sensors 70). The actual path 94 can be compared to the proposed path 96 to determine deviations from the proposed path 96. These deviations can greatly impact the friction between the tubular string 58 and the wellbore 15 during drilling operations. The current disclosure maintains and updates in real time a friction profile for the tubular string 58 operating in the wellbore 15. The friction profile can be used to increase the accuracy of a digital twin simulation of the tubular string 58 in the wellbore 15.

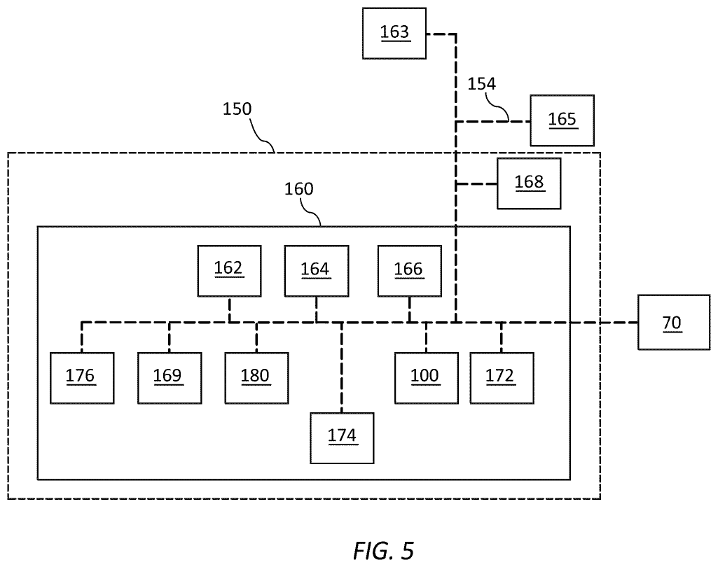

FIG. 5 is a representative functional block diagram of a rig controller 150 that can control rig equipment of the rig 10 and perform methods of the current disclosure (e.g., wrap optimization), in accordance with certain embodiments. The rig controller 150 can include one or more local or remote processing units 160 that can be locally or remotely positioned relative to the rig 10 or downhole. Each processing unit 160 can include one or more processors 162 (e.g., microprocessors, programmable logic arrays, programmable logic devices, etc.), non-transitory memory storage devices 164, peripheral interface 166, human machine interface (HMI) device(s) 168, and possibly a remote telemetry interface 165 for internet communication or satellite network communication. The HMI devices 168 can include a touchscreen, a laptop, a desktop computer, a workstation, or wearables (e.g., smart phone, smart watch, tablet, etc.). These components of the rig controller 150 can be communicatively coupled together via one or more networks 154, which can be wired or wireless networks.

The processors 162 can be configured to read instructions from one or more non-transitory memory storage devices 164 and execute those instructions to perform any of the operations described in this disclosure. A peripheral interface 166 can be used by the rig controller 150 to receive sensor data from around the rig 10 or downhole and can collect data on the rig operations is being performed. The peripheral interface 166 can also be used by the rig controller 150 to send commands to personnel or rig equipment to control rig operations during a subterranean operation. The rig controller 150 can receive a well plan 163 via the network 154 (or peripheral interface 166) and can determine a rig state based on the well plan 163 and data from the sensors 70.

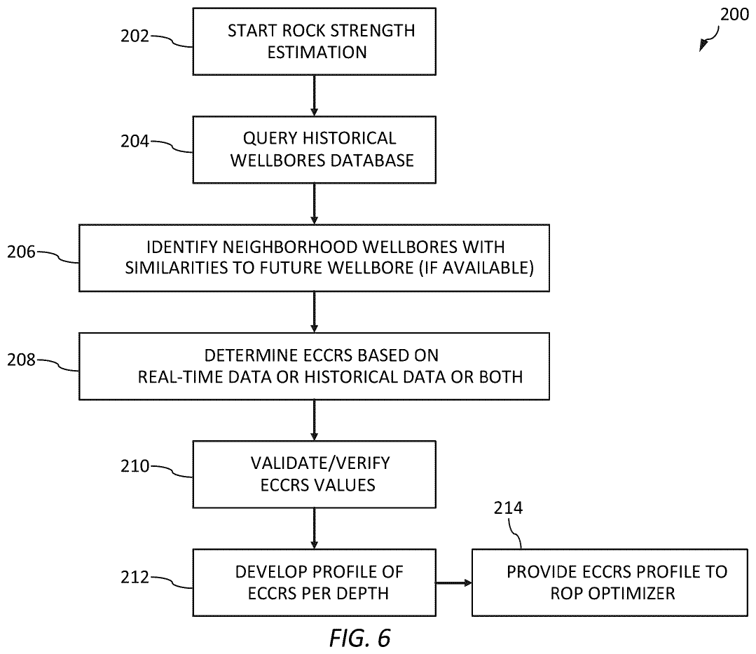

The rig controller 150 can include a rock strength database 169 that can store historical rock strength data from previously drilled wells. This historical rock strength data can be used by a rock strength simulator 172 of the rig controller 150 to determine an equivalent confined compressive rock strength (ECCRS) profile for a future wellbore 15 (see FIG. 6). The ECCRS can be stored in one or more non-transitory memory storage devices 164 for retrieval as needed during operation. A wrap optimizer 100 of the rig controller 150 can use the ECCRS profile, characteristics of the tubular string 58, and characteristics of the wellbore 15 to develop a friction profile of the wellbore 15 by depth.

The rock strength simulator 172 can, based on real-time parameter data received for the current a drilling operation, determine the ECCRS in real-time using equation (1):

$$E C C R S ( realtime ) = \frac{2 W O B}{{D}_{b} ( D O C * z + {L}_{f} )} \qquad Eq . ( 1 )$$

Where ECCRS (realtime) is the real-time results from the rock strength simulator 172 based on the real-time data, WOB refers to weight on bit, Db refers to a drill bit diameter, DOC refers to depth of cut of the drill bit 68, “z” refers to a zeta parameter and Lf refers to a flat length parameter which are constraints dependent on geometries of the drill bit 68. This equation can be used to determine ECCRS in real-time, without having historical rock strength data from offset wellbores to validate the ECCRS.

However, the rock strength simulator 172 can also use historical rock strength data to validate real-time data and identify errors in the real-time data during the real-time simulations for determining ECCRS. The historical rock strength data from one or more offset wellbores (e.g., from the historical rock strength database 169) can be used to compare with predicted ECCRS values as a function of depth to identify any potential errors in the real-time parameter data as well as unexpected changes in the rock formations the rig 10 can be drilling through. With the historical rock strength data, the rock strength simulator 172 can continue to validate and update the estimated ECCRS.

For example, if the estimated ECCRS values for a certain depth are unacceptably different from the historical rock strength values for the same depth, then the rock strength simulator 172 can flag the estimated ECCRS values as being suspect and can run various simulations with various adjusted parameters to recreate substantially equal values to the historical rock strength values. Rock strength simulator 172 can log actual ECCRS values as a function of depth as well as the deviations of the estimated ECCRS values from the actual ECCRS values.

The wrap optimizer 100 can simulate the tubular string 58 operating in the wellbore 15 and can predict wraps that can increase or optimize ROP during slide drilling operations. As the predicted wraps are implemented by the rig 10, a ranking engine 174 can be used to rank (or score) the recommended (or optimal) wraps for optimizing ROP during slide drilling operations. The wrap optimizer 100 can use this ranking to select recommended wraps for a future wellbore 15. The optimal wraps for the wellbore 15 can be stored in an optimal wraps database 180 that associates the optimal wraps with wellbore type, wellbore depth, rock formation, friction profile, geographical region, etc. which can be used to estimate wraps for a future wellbore.

A historical well data database 176 can be used to store all formation and operational parameters for previously drilled wellbores. The information can include all of the equipment recipes used during the wellbore construction, the actual rock formation properties along the wellbore as a function of depth, the geographical region in which the wellbore was constructed, personnel performing each rig activity, wraps used during slide drilling as well as the resulting ROP, the actual as-built well plan/rig plan, and all sensor data from sensors 70.

FIG. 6 is a representative flow diagram of a method 200 for determining an equivalent confined compressive rock strength (ECCRS) profile of a future wellbore 15, in accordance with certain embodiments. The method 200 can begin at operation 202, where the rig controller 150 (or a module of the rig controller 150) begins the process of determining an equivalent (or estimated) confined compressive rock strength (ECCRS) for the roadmap of a future wellbore 15 to be drilled by the rig 10.

The confined compressive rock strength is a parameter that can be used to calculate or predict a friction profile for the wellbore 15 and tubular string 58. The roadmap (or planned wellbore trajectory defined by a well plan 163) of the future wellbore 15 can indicate a strata of the subterranean formation 8 with one or more layers of material (or rock) through which the wellbore 15 is to be extended. The confined compressive rock strength can be used to model an interaction of the tubular string 58 with uncased portions of the wellbore 15.

In operation 204, the rig controller 150 (e.g., the rock strength simulator 172) can sort through the historical rock strength data from previously drilled wells that can be stored in the rock strength database 169. The rig controller 150 can identify the material or rock type at each depth of the future wellbore 15 based on the well plan 163 and develop a rock type profile for the future wellbore 15 based on neighborhood wellbores with similarities to the future (or new) wellbore 15, as in operation 206.

The rock strength simulator 172 can be used to identify the neighborhood wellbores and associated rock strength data from the database 169, if historical rock strength data offset wellbore data is available. However, it is not required that historical rock strength data be available to determine ECCRS for portions of the future wellbore 15. As described above, the rock strength simulator 172 can determine an ECCRS profile without historical rock strength data. The rock strength simulator 172 can also use the historical rock strength data to validate the ECCRS profile values.

In operation 208, with the rock type profile defined, the rock strength simulator 172 can query the rock strength database 169 to determine appropriate rock strength values for the strata through which the future wellbore 15 will be drilled and calculate an equivalent confined compressive rock strength (ECCRS) for the material in the strata.

However, in a case where there is little to no historical rock strength data available from offset wellbores, the rock strength simulator 172 can calculate the ECCRS as a function of depth based on real-time parameter data received from the data sources of the rig 10. If historical rock strength data is available, then the rock strength simulator 172 can use the historical data to validate the ECCRS values determined from the real-time rock strength simulations. The real-time simulations of the rock strength simulator 172 is described in more detail above with regard to FIG. 4.

In operation 210, the ECCRS values can be verified or validated to filter out anomalies or errors detected when comparing to the historical data and ensure that the values are viable when used in the wrap optimizer 100. In operation 212, once the values are validated, the rock strength simulator 172 can develop a profile of ECCRS values versus depth of the future wellbore 15 or at least a portion of the future wellbore 15. In operation 214, the ECCRS can be provided to the wrap optimizer 100 (e.g., a physics-based simulator) for performing a physics-based model simulation to predict the wraps for slide drilling operations along at least a portion of the future wellbore 15.

The ECCRS profile can be modified during real-time physics-based model simulations (e.g., digital twin simulations of slide drilling operations) by the wrap optimizer 100, as needed (e.g., drill bit 68 enters a rock layer earlier than expected, the drill bit exits a rock layer earlier than expected, a different rock layer is encountered than expected, etc.), but usually the ECCRS profile remains generally unchanged after the rock strength simulator 172 provides it to the wrap optimizer 100. However, with the real-time simulations of the rock strength simulator 172, the ECCRS values can change in real-time as desired while the future wellbore 15 is being drilled.

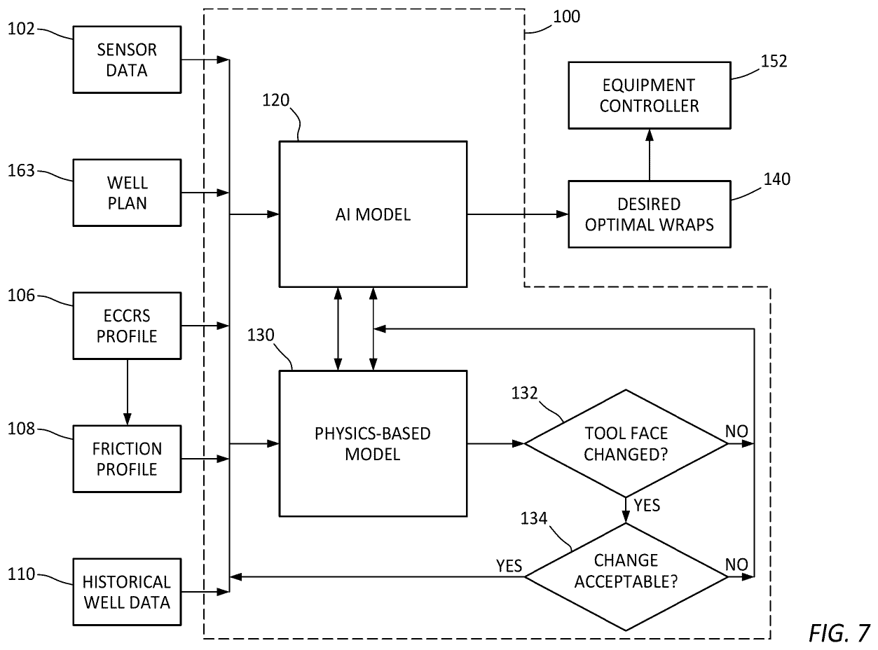

FIG. 7 is a representative functional block diagram of a wrap optimizer for real-time control of wraps of a tubular string 58 during slide drilling operations of a future wellbore 15, in accordance with certain embodiments.

A wrap optimizer 100 can include a physics-based model 130 and an artificial intelligence (AI) model 120. The physics-based model 130 does not need to be taught like an AI model 120 (e.g., a machine learning model, a neural network, etc.). When using an AI model 120, generally to provide meaningful results, a training dataset is used to train the AI model 120. After training, the AI model 120 can provide results based on the inputs provided. However, a physics-based model does not require training to interpret the data inputs. The physics-based model 130 can simulate interaction of the tubular string 58 and the drill bit 68 with the strata based on physical parameters of the system. The wrap optimizer 100 can also adjust various physical parameters to detect the sensitivity of the wrap predictions based on the physical parameters.

In the physics-based model 130 (e.g., transient dynamics model, or time domain models, etc.) the tubular string 58 (including the BHA 60) can be discretized coarsely as rigid and flexible beam elements interconnected via viscoelastic connections. Any beam element will theoretically undergo an arbitrary rigid body motion and a small elastic deformation. Modeling identifies active contact forces such as between the tubular string 58 and wellbore 15 and between the drill bit 68 and the rock of the strata. This enables a realistic evaluation of tubular string 58 dynamics, critical deformations, and failure modes (stick slip, stuck drill string, stuck bit, vibrations, etc.). The interaction is modeled with discrete contact, normally and tangentially, accounting for geometry variation. The dynamic effects of fluids on the string are reduced to buoyancy forces modeled as additional masses and frequency-dependent external damping.

Flexible beams can be used for modeling the tubular string 58 sections of uniform geometry and density (uniform sections). Equations of motions of beams can be generated on the basis of analytical solutions. The uniform sections are connected in the assembly with viscous-elastic force elements of high stiffness.

As long as the flexibility and damping of the pipes are considered with flexible beam models, the values of coupling element parameters (e.g., stiffness constants for three linear and angular directions, and corresponding damping parameters) can be theoretically infinite. The finite values of the parameters are optimized to provide acceptable results with minimal calculation time.

However, an AI model 120 can also provide benefits when used in tandem with the physics-based model 130. The current wrap optimizer 100 can include an AI model 120 that can provide estimated input parameters or adjusted input parameters to the physics-based model 130 for simulation. The AI model 120 can consume parameters from previously drilled wellbores and can estimate from these parameters based on the performance of the previous wellbore operations. However, as stated above, the AI model 120 must be trained to be able to make appropriate estimations. In the current configuration, the physics-based model 130 can be used to train (or “mentor”) the AI model 120 to facilitate accelerated training.

The inputs to the physics-based model 130 can also be input to the AI model 120. Running a simulation with the physics-based model 130 can produce accurate results based on the physical parameters of the wellbore 15 and tubular string 58. The AI model 120 can receive the same inputs of the physics-based model 130 as well as receiving the outputs (results) from the physics-based model 130. Therefore, the physics-based model 130 can be used to train the AI model 120 as to what results are expected based on the input parameters.

If the AI model 120 needs to know what results a particular group of parameters will yield, the AI model 120 can input the parameters into the physics-based model 130 and receive the answer at the outputs of the physics-based model 130. Also, instead of this active training, the AI model 120 can merely observe the inputs and subsequent results from the physics-based model 130 and learn passively. Therefore, the wrap optimizer 100 of the current disclosure can be seen as a physics-informed AI optimizer.

The AI model 120 can consume the historical well data 110 from previously drilled wellbores to determine wraps used in the past for rock formations that are at least similar to the rock formations included in the rock profile of the current (or future) wellbore 15. The AI model 120 can then predict the best wraps for each rock formation in the current wellbore 15 based on the historical well data 110. This can provide a starting point for developing the optimum wraps for the current wellbore 15.

The AI model 120 can then input the recommended wrap profile for the current wellbore 15 to the physics-based model 130. The physics-based model 130 can take the recommended wrap profile and simulate the wraps in the wrap profile as a function of depth. The physics-based model 130 can include a 3D model of the wellbore 15 and a model of the tubular string 58 based on information from the well plan 163. These 3D models can be refined or revised in real time as the wellbore 15 is extended into the earthen formation 8 to account for discrepancies or deviations from the well plan 163.

The physics-based model 130 can simulate the wraps of the tubular string 58 to determine if the optimum wrap parameters are being used. The physics-based model 130 can monitor virtual (or soft) sensors along the tubular string 58 to provide information of wrap progression along the tubular string 58, especially above and below the mud motor 64 and at the drill bit 68. These virtual sensors can indicate when the simulation causes the tool face to change its orientation due to the wraps being simulated.

Generally, the optimum wrap can be where the tool face changes slightly when the wrap reaches the BHA 60 and the next cycle of the wrap progression acts on the BHA 60 to prevent further movement of the tool face. The next cycle of the wrap progression then causes the tool face to change slightly in an opposite direction but again further movement in the opposite direction is prevented due to the next cycle of the wrap progression.

If the tool face does not move, this can indicate that the wrap was not strong enough or sustained long enough to reach the farthest distance in the wellbore 15 (e.g., the BHA 60) before the oppositely directed wrap changes the direction of the rotation of the tubular string 58. If the tool face moves too much before the next cycle of the wrap progression acts to rotate the tool face in the opposite direction, then this can indicate that the wrap is too strong and needs to be adjusted to prevent loss of direction control of the drill bit 68.

Therefore, the optimum wraps can be when the sensor data indicates that the tool face only slightly rotates (i.e., within an acceptable amount of rotation, such as +/−20 degrees) before the next cycle of the wrap progression acts to move the tool face in an opposite direction. This can be referred to as optimum results for a wrap. The physics-based model 130 is continually updated for varying wellbore 15 and tubular string 58 parameters (e.g., increasing length, increasing depth, increasing friction, varying rock formations, varying pipe tally, etc.) to provide an acceptably accurate digital twin simulation for emulating wraps of the tubular string 58 during slide drilling operations.

Additionally, optimum results for a wrap can also be seen as when a virtual sensor 170 indicates the desired movement at any location along the tubular string 58. For example, a virtual sensor 170 at a location just above the BHA 60 can detect movement of the tubular string 58 before the BHA 60 is moved by the wrap progression. If it is desired for the wrap to reach the BHA 60 but not to move the BHA 60, then this virtual sensor 170 can detect when the optimum results are achieved (e.g., movement of the virtual sensor 170, but not the BHA 60) which can indicate minimum to no movement of the tool face. The optimum results are those results that achieve a desired performance of the wraps.

The physics-based model 130 can input real time sensor data 102 from various sensors 70 to validate the performance of the digital twin simulation as well as refine the simulation parameters based on changing characteristics. For example, the tool face can be calculated from real time sensor data 102 from the sensors 70 and compared to the virtual sensors in the physics-based model 130 to ensure the digital twin is operating within an acceptable error range. The physics-based model 130 can input real time sensor data 102 from various sensors 70 to refine the simulation parameters based on changing characteristics. For example, changing the simulation parameters as the wellbore 15 is extended further into the earthen formation 8.

With the best estimated wraps for each rock formation in the current wellbore 15 determined by the AI model 120 based on the historical well data 110, the AI model 120 can begin validating these estimated wraps by inputting the wrap parameters into the physics-based model 130 to determine if they produce the optimum results (as defined above). Depending upon the results of each of the estimated wraps in the wrap profile, the AI model 120 can begin to provide adjusted parameters to adjust the estimated wraps to iteratively approach the desired optimal results.

The continual training of the AI model 120 can continue to reduce the iteration cycles needed to reach the optimal results. When the optimal results are achieved for each of the wraps in the overall wrap profile for the wellbore 15, these wraps can be seen as the desired optimal wraps profile. These desired optimal wraps can be stored in the optimal wraps database 180 for future wrap estimations.

With the desired optimal wraps 140 established, the physics-based model 130 can begin simulating the slide drilling operation as a digital twin of the actual slide drilling operation. The desired optimal wraps can be implemented by the rig 10 (e.g., communicated to rig equipment controllers 152 to perform wraps) during the actual slide drilling operation while the desired optimal wraps 140 are also being simulated by the digital twin. The sensor data from sensors 70 can be used to monitor the tool face of the actual BHA 60 and detect if the tool face is rotating outside of the acceptable range.

If so, the physics-based model 130 can determine the amount of error between the actual wraps (e.g., the desired optimal wraps 140) and the simulated desired optimal wraps. The physics-based model 130 can update the digital twin simulation based on the latest sensor data and the latest wellbore 15 and tubular string 58 parameters. The physics-based model 130 can rerun the digital twin with the desired optimal wraps 140 to see if the error is corrected.

The AI model 120 can also determine adjusted wrap parameters that can adjust the actual wraps to produce optimal results. The AI model 120 can input the adjusted wrap parameters into the physics-based model 130 (or an updated physics-based model 130) to determine a predicted response of the slide drilling operation to the adjusted parameters. When the physics-based model 130 and AI model 120 agree on new desired optimal wraps 140, then these can be communicated to the equipment controllers 152 to be implemented by the rig 10. When sufficient regional well data is available for training, the AI model 120 can independently or in conjunction with the physics-based model 130 can accurately predict and advise the desired wrap parameters.

Once the desired optimal wraps 140 have been determined, the physics-based model 130 is ready to perform the digital twin simulation for a slide drilling operation for which the desired optimal wraps 140 were developed. The rig controller 150 (e.g., via the physics-based model 130) can determine (e.g., based on sensor data and the well plan 163) that the rig state is slide drilling and that the rock formation(s) being drilled correlate to the expected rock formations of the digital twin simulation. The physics-based model 130 can begin running the digital twin simulation to monitor the progression of wraps along the tubular string 58.

The actual drilling or formation parameters can be monitored in real time via the sensors 70. The digital twin simulation can be updated in real time if the actual drilling or formation parameters are determined to be different than the simulation drilling or formation parameters (e.g., different rock formation properties, different friction parameters, different mud flow, different mud parameters, deviations from the wellbore proposed path, etc.).

During the slide drilling operation, the physics-based model 130 can monitor downhole progression of the wraps by monitoring the wrap progression in the digital twin. The virtual sensors can allow the rig controller 150 or rig operators to monitor the tubular string 58 performance during wraps being applied to the tubular string 58. If the digital twin indicates that the tool face is moving more than an acceptable amount, then the digital twin can be used to determine adjustments to the wrap parameters to correct the wraps, such that the tool face movement is reduced to an acceptable amount.

Additionally, if the digital twin detects that the tool face is not being moved, then the digital twin can be used to determine adjustments to the wrap parameters to correct the wraps, such that the tubular string 58 wraps are changed to cause the tool face to move, but to keep the movement within an acceptable amount. When the wrap adjustments are confirmed by the digital twin to produce the optimum results, then the adjusted wrap parameters can be communicated (e.g., via a wired or wireless network) to the rig controller 150 (or equipment controllers 152) to implement the adjusted wraps. This process can continue throughout the slide drilling operation to continually monitor the wrap results and adjust the wrap parameters as needed to substantially maintain the wrap results within the optimum results range.

It can be seen that the physics-based model 130 is continually (or at least periodically or randomly) monitoring to see if the tool face is changed in operation 132. If the tool face is not changed, then the AI model 120 (or physics-based model 130) can be alerted to adjust the wrap parameters (e.g., such as increase RPM, increase duration, etc.) until the tool face moves.

In operation 132, if the tool face moves, then the process can proceed to operation 134 that can determine if the tool face movement is within an acceptable amount. If the tool face movement is greater than the acceptable amount, then the AI model 120 (or physics-based model 130) can be alerted to adjust the wrap parameters (e.g., such as decrease RPM, decrease duration, etc.) until the tool face movement is reduced to within an acceptable range.

If the movement is within an acceptable range, then the AI model 120 (or physics-based model 130) can be alerted to score the current wrap parameters as being optimum for the current slide drilling and tubular string parameters. These wrap parameters can also be stored in the optimal wraps database 180.

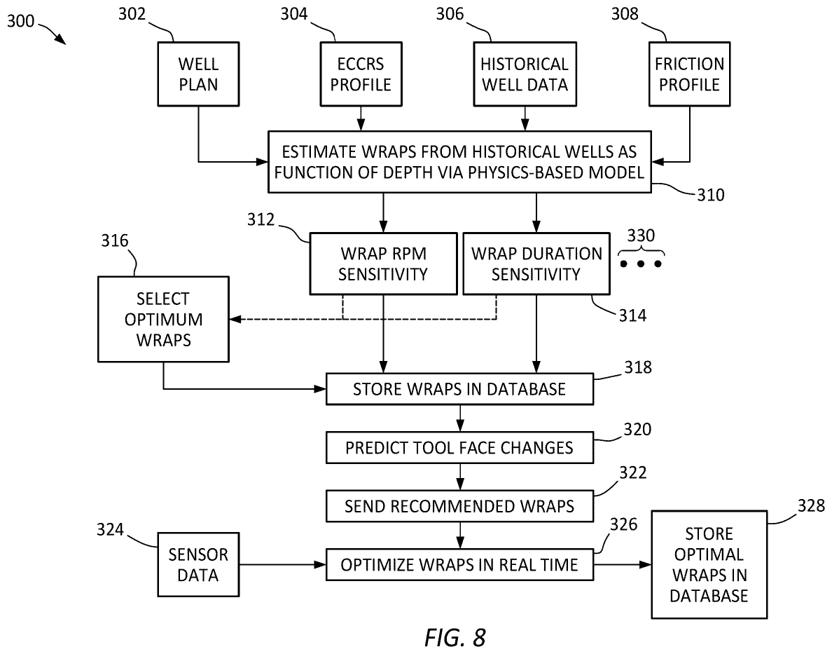

FIG. 8 is a representative flow diagram of a method 300 for real-time control of wraps of a tubular string 58 during slide drilling operations of a wellbore 15, in accordance with certain embodiments. In operation 310, the AI model 120 can receive detailed wellbore drilling construction information from the well plan 163 from operation 302. The well plan 163 can provide detailed information about the roadmap of the proposed wellbore 15 as well as a rock strength profile for the proposed wellbore 15. As described above, the ECCRS profile 106 can be determined in operation 304 and provided for simulating interaction between the drill bit 68 and the rock formations.

In operation 308, the friction profile 108 can be determined based on the tubular string 58 properties, the proposed wellbore 15 properties, and the ECCRS profile 106. Using historical well data 110, ECCRS profile 106, an inverse numerical method can be used to estimate friction factors along the wellbore 15. The inverse method can start with an initial friction factor and calculate parameters like hook load or weight on bit (WOB). These calculated values can be compared against historical well data 110, and the friction factors can be updated/adjusted until the calculated values significantly agree with the historical values.

With the well type, wellbore roadmap, ECCRS profile 106, the region, and the rig equipment established, then, in operation 306, historical well data from previously drilled wellbores can be provided to the AI model 120 (such as from the historical well data database 176). This historical well data can include the well construction data, the operational data used to construct the wellbore, the rock strength profile of the wellbore, ROP performance as a function of depth, as-constructed well plan/rig plan information, etc.

The AI model 120 can search the historical well data database 176 to identify similar wellbores with similar characteristics, as well as similar construction characteristics, and from this historical data (and possibly data from the optimal wraps database 180), the AI model 120 can determine a wrap profile as a function of depth for the proposed wellbore roadmap of the proposed wellbore 15. The AI model 120 can determine effective and best fit wraps for each rock formation along the wellbore roadmap where slide drilling is planned.

Once the AI model 120 has developed an estimated wrap profile as a function of depth for the proposed wellbore 15, then the AI model 120 can begin running the wrap parameters for the wraps in the wrap profile through the physics-based model 130. In the beginning of the wellbore 15, the physics-based model 130 can include expected wellbore properties, expected tubular string 58 properties (or characteristics), and expected well plan activities. The AI model 120 can use the physics-based model 130 to optimize the estimated wraps in the estimated wrap profile. The estimated wraps can be optimized by adjusting the wrap parameters such that the wraps produce the optimum results (e.g., tool face moves but only within an acceptable range).

In operations 312, 314 (and possibly 330), the physics-based model 130 can be used by the AI model 120 to determine sensitivity of the wrap results to various wrap parameters (e.g., tubular string RPM, wrap duration, etc.). The resulting optimized wraps can be provided to operation 318 for selecting which wraps to use, or they can be sent to operation 316, which can use the ranking engine 174 to compare performance of the optimum estimated wraps from the operations 312, 314, 330 and select which of the optimum estimated wraps to recommend for the slide drilling operation.

In operation 318, the rig controller 150 can determine which of the optimum wraps for the particular slide drilling operation can best provide the optimum results. The selected wraps can be provided to the operation 320 to predict tool face changes caused by the selected wraps. The selected wraps can be stored in the optimal wraps database 180 for future reference for the current wellbore 15 or future wellbores.

In operation 320, the AI model 120 can input the selected wraps to the physics-based model 130 which can perform a digital twin simulation of the particular slide drilling operation using the recommended wraps to predict tool face changes. The AI model 120 can adjust the wrap parameters to achieve the optimum results for the particular slide drilling operation, if the recommended parameters do not produce the optimum results.

In operation 322, the selected wraps can be provided as recommended wraps to the rig controller 150 (or equipment controllers 152) to be implemented when the particular slide drilling operation is performed.

In operation 326, the recommended or adjusted wraps can be implemented by the rig controller 150 to perform wraps of the tubular string 58 during the particular slide drilling operation. The physics-based model 130 can also implement the recommended or adjusted wraps in the digital twin simulation that can mirror the operation of the actual rig 10 or perform a look-ahead simulation that provides early indications of adjustments that may need to be made, such as if the wraps appear to stop producing the optimum results.

Sensor data from sensors 70 can be received from operation 324 to monitor the actual tool face resulting from the recommended or adjusted wraps being used in the particular slide drilling operation of the rig 10. The sensor data can indicate changes in the tubular string 58, the wellbore parameters, the rig equipment operations, the actual path of the wellbore 15, the rig state, as well as other information. The rig controller 150 can continually (or at least periodically) update the physics-based model 130 based on the real time parameters of the tubular string 58 and the wellbore 15, which can include updates to the friction profile 108.

Updates to the physics-based model 130 may be needed to keep the performance of the digital twin simulation as close to operations of the actual rig 10 as possible. As the physics-based model 130 is updated, it can run or rerun the recommended or adjusted wraps to verify that the optimum results are still provided. However, if the digital twin simulation indicates that the optimum results are no longer provided, then the AI model 120 or the physics-based model 130 can adjust the wraps as needed to provide optimum results again.

The physics-based model 130 can continue to perform the digital twin simulation to provide detailed insight into the wrap progression of the tubular string 58 during the slide drilling operations. In operation 328, the optimal wraps that are determined by the physics-based model 130 can be stored with all pertinent operational data in the optimal wraps database 180 for estimating future wraps for the current wellbore 15 or a future wellbore.

### Various Embodiments

Embodiment 1. A method of optimizing tubular string wraps in real-time during a subterranean operation, the method comprising:
determining, via a rig controller, a friction model of a wellbore as a function of depth; simulating, via a physics-based model, a digital twin, wherein the digital twin simulates interactions between a tubular string and the wellbore based on the friction model;
adjusting, via the physics-based model, parameters of estimated wraps for oscillating the tubular string in the wellbore in the digital twin simulation;
identifying, via the digital twin, optimum parameters for simulated wraps based on the adjusted parameters of the estimated wraps;
communicating, via the physics-based model, the optimum parameters to the rig controller; and
producing, via the rig controller, actual wraps of the tubular string in the wellbore based on the optimum parameters.

Embodiment 2. The method of embodiment 1, further comprising:
monitoring, via the rig controller, an actual tool face of a bottom hole assembly (BHA);
comparing the actual tool face to a simulated tool face; and
adjusting, via a physics-based model, the optimum parameters in real time to correct a discrepancy between the actual tool face and the simulated tool face.

Embodiment 3. The method of embodiment 1, further comprising:
receiving sensor data from a rig;
determining, via the rig controller, changing parameters of the wellbore or the tubular string;
updating, via the rig controller, the physics-based model based on the changing parameters; and
monitoring, via the updated physics-based model, tool face movement in the digital twin.

Embodiment 4. The method of embodiment 1, wherein the physics-based model comprises an unsteady-state physics model or a fast running time domain analysis model.

Embodiment 5. The method of embodiment 1, wherein the physics-based model simulates the tubular string as being discretized coarsely as rigid and flexible beam elements interconnected via viscoelastic connections.

Embodiment 6. The method of embodiment 1, wherein adjusting the parameters of the estimated wraps further comprises:
producing, via the physics-based model, the estimated wraps of the tubular string in the digital twin;
monitoring, via the physics-based model, progression of the estimated wraps along the tubular string in the digital twin; and
monitoring, via the physics-based model, a virtual sensor at a preferred location along the tubular string in the digital twin.

Embodiment 7. The method of embodiment 6, further comprising:
detecting, via the physics-based model, that movement of the tubular string at the virtual sensor is zero or is more than an acceptable amount during production of the estimated wraps by the digital twin, wherein the acceptable amount is +/−20 degrees of rotation; and
adjusting, via the rig controller, the parameters of the estimated wraps until the movement of the tubular string at the virtual sensor is non-zero and within the acceptable amount.

Embodiment 8. The method of embodiment 7, wherein the rig controller comprises an artificial intelligence (AI) model that adjusts the estimated parameters to identify the optimum parameters and communicates the optimum parameters to the physics-based model which simulates wraps of the tubular string based on the optimum parameters, wherein the optimum parameters produce optimum results in rotation of the tubular string.

Embodiment 9. The method of embodiment 8, wherein the artificial intelligence (AI) model comprises a machine learning model or a neural network.

Embodiment 10. The method of embodiment 1, further comprising:
producing, via the physics-based model, the estimated wraps of the tubular string in the
monitoring, via the physics-based model, progression of the estimated wraps along the tubular string in the digital twin simulation; and
monitoring, via the physics-based model, a simulated tool face of the tubular string in the digital twin simulation.

Embodiment 11. The method of embodiment 10, further comprising:
detecting, via the physics-based model, that movement of the simulated tool face is zero during production of the estimated wraps; and
adjusting, via the rig controller, the estimated parameters until the movement of the simulated tool face is non-zero.

Embodiment 12. The method of embodiment 11, wherein the rig controller comprises an artificial intelligence (AI) model that adjusts the estimated parameters to identify the optimum parameters and communicates the optimum parameters to the physics-based model which simulates wraps of the tubular string based on the optimum parameters.

Embodiment 13. The method of embodiment 1, wherein determining the friction model further comprises:
determining, via a statistical model, an equivalent confined compressive rock strength (ECCRS) profile along the wellbore; and
retrieving, via the statistical model, historical rock strength properties associated with one or more previously drilled wellbores.

Embodiment 14. The method of embodiment 1, wherein simulating the digital twin further comprises simulating at least one of:
simulating sensitivity of wrap performance to wrap revolutions per minute (RPM);
simulating sensitivity of wrap performance to wrap duration; or
a combination thereof.

Embodiment 15. The method of embodiment 14, further comprising selecting the optimum parameters based on the wrap performance.

Embodiment 16. The method of embodiment 1, wherein the rig controller comprises an artificial intelligence (AI) model.

Embodiment 17. The method of embodiment 16, further comprising:
determining, via the AI model and the physics-based model, the estimated wraps from previously drilled wellbores, wherein the AI model searches data from the previously drilled wellbores and identifies previous wrap parameters for similar rock formations in the previously drilled wellbores.

While the present disclosure may be susceptible to various modifications and alternative forms, specific embodiments have been shown by way of example in the drawings and tables and have been described in detail herein. However, it should be understood that the embodiments are not intended to be limited to the particular forms disclosed. Rather, the disclosure is to cover all modifications, equivalents, and alternatives falling within the spirit and scope of the disclosure as defined by the following appended claims. Further, although individual embodiments are discussed herein, the disclosure is intended to cover all combinations of these embodiments.

What is claimed is:

1. A method of optimizing tubular string wraps in real-time during a subterranean operation, the method comprising:
determining, via a rig controller, a friction model of a wellbore as a function of depth;
simulating, via a physics-based model, a digital twin, wherein the digital twin simulates interactions between a tubular string and the wellbore based on the friction model;
adjusting, via the physics-based model, parameters of estimated wraps for oscillating the tubular string in the wellbore in the digital twin simulation;
identifying, via the digital twin, optimum parameters for simulated wraps based on the adjusted parameters of the estimated wraps;
communicating, via the physics-based model, the optimum parameters to the rig controller; and
producing, via the rig controller, actual wraps of the tubular string in the wellbore based on the optimum parameters.

2. The method of claim 1, further comprising:
monitoring, via the rig controller, an actual tool face of a bottom hole assembly (BHA);
comparing the actual tool face to a simulated tool face; and
adjusting, via the physics-based model, the optimum parameters in real time to correct a discrepancy between the actual tool face and the simulated tool face.

3. The method of claim 1, further comprising:
receiving sensor data from a rig;
determining, via the rig controller, changing parameters of the wellbore or the tubular string;
updating, via the rig controller, the physics-based model based on the changing parameters; and
monitoring, via the updated physics-based model, tool face movement in the digital twin.

4. The method of claim 3, further comprising:
monitoring, via the sensor data, tool face movement of a BHA in the wellbore; and
adjusting the digital twin to correct a discrepancy between the tool face movement of the BHA and the tool face movement in the digital twin.

5. The method of claim 1, wherein the physics-based model comprises an unsteady-state physics model or a fast running time domain analysis model.

6. The method of claim 1, wherein the physics-based model simulates the tubular string as being discretized coarsely as rigid and flexible beam elements interconnected via viscoelastic connections.

7. The method of claim 1, wherein adjusting the parameters of the estimated wraps further comprises:
producing, via the physics-based model, the estimated wraps of the tubular string in the digital twin;
monitoring, via the physics-based model, progression of the estimated wraps along the tubular string in the digital twin; and
monitoring, via the physics-based model, a virtual sensor at a preferred location along the tubular string in the digital twin.

8. The method of claim 7, further comprising:
detecting, via the physics-based model, that movement of the tubular string at the virtual sensor is zero or is more than an acceptable amount during production of the estimated wraps by the digital twin, wherein the acceptable amount is within +/−20 degrees of rotation; and
adjusting, via the rig controller, the parameters of the estimated wraps until the movement of the tubular string at the virtual sensor is non-zero and within the acceptable amount.

9. The method of claim 8, wherein the rig controller comprises an artificial intelligence (AI) model that adjusts the estimated parameters to identify the optimum parameters and communicates the optimum parameters to the physics-based model which simulates wraps of the tubular string based on the optimum parameters, wherein the optimum parameters produce optimum results in rotation of the tubular string.

10. The method of claim 9, wherein the artificial intelligence (AI) model comprises a machine learning model or a neural network.

11. The method of claim 1, further comprising:
producing, via the physics-based model, the estimated wraps of the tubular string in the digital twin simulation;
monitoring, via the physics-based model, progression of the estimated wraps along the tubular string in the digital twin simulation; and
monitoring, via the physics-based model, a simulated tool face of the tubular string in the digital twin simulation.

12. The method of claim 11, further comprising:
detecting, via the physics-based model, that movement of the simulated tool face is zero during production of the estimated wraps; and
adjusting, via the rig controller, the estimated parameters until the movement of the simulated tool face is non-zero.

13. The method of claim 12, wherein the rig controller comprises an artificial intelligence (AI) model that adjusts the estimated parameters to identify the optimum parameters and communicates the optimum parameters to the physics-based model which simulates wraps of the tubular string based on the optimum parameters.

14. The method of claim 1, wherein determining the friction model further comprises:
determining, via a rock strength simulator, an equivalent confined compressive rock strength (ECCRS) profile along the wellbore; and
retrieving, via the rock strength simulator, historical rock strength properties associated with one or more previously drilled wellbores.

15. The method of claim 1, wherein determining the friction model further comprises:
determining, via a rock strength simulator, an ECCRS in real time based on data from one or more downhole sensors.

16. The method of claim 1, wherein simulating the digital twin further comprises simulating at least one of:
simulating sensitivity of wrap performance to wrap revolutions per minute (RPM);
simulating sensitivity of wrap performance to wrap duration; or
a combination thereof.

17. The method of claim 16, further comprising selecting the optimum parameters based on the wrap performance.

18. The method of claim 1, wherein the rig controller comprises an artificial intelligence (AI) model.

19. The method of claim 18, further comprising:
determining, via the AI model and the physics-based model, the estimated wraps from previously drilled wellbores, wherein the AI model searches data from the previously drilled wellbores and identifies previous wrap parameters for similar rock formations in the previously drilled wellbores.

20. The method of claim 18, further comprising:
using the physics-based model to train the AI model, by monitoring, via the AI model, inputs and outputs of the physics-based model with the outputs being a desired outcome from the inputs received at the physics-based model.
